(19) United States
(12) Patent Application Publication
(10) Pub. No.: US 2009/0149031 A1
(43) Pub. Date: Jun. 11, 2009

(54) Method of making a semiconductor device with residual amine group free multilayer interconnection

(75) Inventors: Katsumi Kakamu, Kasugai (JP); Hirofumi Watatani, Kawasaki (JP); Masanobu Ikeda, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/289,227

(22) Filed: Oct. 23, 2008

Related U.S. Application Data
(62) Division of application No. 10/385,729, filed on Mar. 12, 2003, now abandoned.

(30) Foreign Application Priority Data
Jun. 7, 2002 (JP) 2002-166897

(51) Int. Cl. H01L 21/31; H01L 21/02

(52) U.S. Cl. 438/763; 438/787; 257/E21.002; 257/E21.24

(57) ABSTRACT

The present invention provides a semiconductor device that can restrict the dissolution hindering phenomenon in a chemically amplified resist film. More specifically, after the formation of a contact pattern on a semiconductor substrate, a wiring pattern is formed on the contact pattern. A SiC film, a first SiOC film, a SiC film, a second SiOC film, a USG film as a diffusion preventing film, and a silicon nitride film as a reflection preventing film, are formed on the wiring pattern. A dual damascene structure is then formed using the chemically amplified resist film and another chemically amplified resist film. In this manner, the N₂ gas generated during the formation of the silicon nitride film as a reflection preventing film can be prevented from diffusing into the second SiOC film formed under the silicon nitride film. Accordingly, the reaction of the N₂ gas with the H group contained in the second SiOC film and the generation of an amine group such as NH in the second SiOC film can be prevented. Thus, the dissolution hindering phenomenon in the chemically amplified resist film can be avoided.

### INCORPORATION-BY-REFERENCE TO RELATED APPLICATIONS

This application is a divisional application of Ser. No. 10/385,729, filed Mar. 12, 2003, and is based upon and claims the benefit of priority from the prior Japanese Patent Application No. 2002-166897, filed in Jun. 7, 2002, the entire contents of which are incorporated by reference.

### BACKGROUND OF THE INVENTION

The present invention generally relates to semiconductor devices, and, more particularly, to a semiconductor device that is formed with an oxide film containing C or H as an interlayer insulating film and a chemically amplified photoresist.

There has been an increasing demand for smaller semiconductor devices that consume less electricity and yet are capable of performing higher-speed operations. To satisfy such a demand, a Cu-damascene process using Cu with a lower resistivity is employed to form wiring structures, especially, multilayered interconnection structures. At the same time, employment of low-dielectric-constant interlayer insulating films in the multilayered interconnection structures has been considered to reduce a parasitic capacity. The demand for a reduction of the dielectric constant of an interlayer insulating film material has been increasing with the reductions in the sizes of ULSIs.

An example of the low-dielectric-constant films are a SiOC film.

As semiconductor devices have become smaller, KrF excimer lasers (of a wavelength of 248 nm) have been employed as the exposing light source for the photolithography technique of forming minute patterns. Chemically amplified resist films that have high penetrability with far ultraviolet rays and so excellent sensitivity as to form minute patterns are employed as resist films for KrF excimer lasers.

As the wavelength of the light source becomes shorter, however, the reflectivity of the substrate of the semiconductor device becomes higher, and the wavelength is restricted to a narrower band, often resulting in a standing wave. With a standing wave, a defective pattern might be caused due to light leakage at the stepwise part of the semiconductor device, and the resolution line width is periodically varied with a change of the resist film thickness. Therefore, etching should be performed on a film to be processed, after formation of a reflection preventing film having a standing wave restricting effect on the film to be processed.

As a method of preventing a defective pattern on a resist film, Japanese Laid-Open Patent Application No. 11-97442 discloses a structure and process illustrated in FIGS. 1A and 1B in which an A1 wiring pattern is to be formed.

FIGS. 1A and 1B illustrate a process of manufacturing a semiconductor device that employs the conventional reflection preventing film and a reaction preventing film.

As shown in FIG. 1A, a silicon oxide film 2, an aluminum wiring 3, a silicon oxynitride film 4 that is to serve as a reflection preventing film, a silicon oxide film 5 that is to serve as a reaction preventing film, and a chemically amplified resist film 6, are formed in this order on a semiconductor substrate 1.

The objective of the formation of the silicon oxynitride film 4 is to provide a reflection preventing film for restricting standing wave effects. However, the silicon oxynitride film 4 is unstable as it is. As a result, alkalis such as ammonia (NH₃) and amine (R—NH₂) adhere to the surface of the silicon oxynitride film 4, and cause a neutralization reaction with the acids contained in the chemically amplified resist film 6. Such a neutralization reaction leads to problems of hindering an oxidation reaction of the chemically amplified resist film 6, and preventing the formation of a pattern on the chemically amplified resist film 6.

To avoid the problems, the silicon oxide film 5 as a chemically stable reaction preventing film is formed between the silicon oxynitride film 4 and the chemically amplified resist film 6. Also, the silicon oxide film 5 restricts the occurrence of pattern dragging on the interface with the chemically amplified resist film 6.

After the formation of the silicon oxynitride film 4 that is to be a reflection preventing film and the silicon oxide film 5 that is to be a reaction preventing film on the aluminum wiring 3, the chemically amplified resist film 6 is patterned, as shown in FIG. 1B, so that the standing wave can be restricted and the adhesion of alkalis onto the reflection preventing film can also be prevented. Accordingly, resist pattern dragging can be avoided, and a pattern that has little standing wave effect and excels in line width controllability can be obtained.

As described above, there has been an increasing demand for smaller, less energy-consuming, and higher-speed semiconductor devices. To satisfy such a demand, employment of low-dielectric-constant interlayer insulating films in semiconductor devices has been suggested. Examples of insulating films that can be employed as low-dielectric-constant interlayer insulating films include SiOC films.

The source gases for a SiOC film include Si(CH₃)₄, Si (CH₃)₃H, and the like. A SiOC film is a low-dielectric-constant insulating film that is formed by a plasma CVD method.

FIG. 2 shows the results of FT-IR (Fourier transform infrared spectrum) measurement carried out on an USG (undoped silicate glass) film and a SiOC film.

As can be seen from FIG. 2, the SiOC film is an oxide film that includes a C—H group, a Si—CH₃ group, a SiC group, and a Si—OCH group therein. The film density of such a SiOC film is as low as 1.3 g/cc. The USG film is an oxide film formed by a CVD method. In the USG film, only SiO coupling can be observed. Also, the USG film has a high density and a high dielectric constant, not including an actual dopant such as C.

FIGS. 3 through 8 illustrate a conventional process of manufacturing a semiconductor device in which a SiOC film is employed as an interlayer insulating film.

As shown in FIG. 3, after the formation of a silicon nitride film 111 and an interlayer insulating film 151 on a semiconductor substrate 101, a chemically amplified resist film for forming a contact hole (not shown) is patterned on the interlayer insulating film 151, and is then etched to form the contact hole (not shown).

A tight contact layer 121 is then formed along the inner walls of the contact hole (not shown). After the filling of the contact hole with a tungsten film 131, excessive parts of the tight contact layer 121 and the tungsten film 131 are removed by a CMP method to form a contact pattern 141. A silicon nitride film 112, a SiOC film 161, and a silicon nitride film that is to be a reflection preventing film, are then formed in this order on the contact pattern 141. A chemically amplified resist film (not shown) for forming a wiring pattern is formed on the silicon nitride film, and a resist window of a shape corresponding to a desired wiring pattern is formed.

With the chemically amplified resist film being a mask, etching is performed, and a wiring pattern groove (not shown) is formed through the silicon nitride film 301, the silicon nitride film 112, and the interlayer insulating film 151.

A Ta film is formed along the inner walls of the wiring pattern groove, and a Cu film is formed to fill the groove. Excessive parts of the Ta film, the Cu film and the silicone nitride film are then removed from the upper surface of the SiOC film 161 by a CMP method, so that a wiring pattern 211 made up of the Ta film 191 and the Cu film 201 is formed only inside the wiring pattern groove.

In the step shown in FIG. 3, a silicon nitride film 113, a SiOC film 162, a silicon nitride film 114, a SiOC film 163, and a silicon nitride film 302 that is to serve as a reflection preventing film, are formed in this order on the wiring pattern 211.

A chemically amplified resist film 182 for forming a via pattern is then patterned on the silicon nitride film 302 as a reflection preventing film, so as to form a resist window 182a, as shown in FIG. 4.

As in the case of the resist window 182a shown in FIG. 4, the leader line leading to the wall in the drawing indicates the entire space.

As shown in FIG. 5, etching is then performed, with the chemically amplified resist film 182 being a mask. As a result, the shape of the resist window 182a is transferred to the SiOC film 162, the silicon nitride film 114, the SiOC film 163, and the silicon nitride film 302 as a reflection preventing film. Accordingly, an opening 162a, an opening 114a, an opening 163a, and an opening 302a, all of which have a corresponding shape to the resist window 182a, are formed.

A protection film 221 made of a material such as resin is then formed in the opening 162a on the silicon nitride film 113, as shown in FIG. 6.

As shown in FIG. 7, a chemically amplified resist film 183 having a resist opening 183b of a shape corresponding to a desired wiring pattern is then formed on the silicon nitride film 302 as a reflection preventing film. In the step shown in FIG. 8, dry etching is performed on the silicon nitride film 302 and the SiOC film 163 thereunder, with the chemically amplified resist film 183 being a mask. As a result, a wiring groove pattern of a shape corresponding to the resist opening 183b is formed.

The protection film 221 is then removed from the via pattern 162a. After the formation of a barrier metal film made of a material such as Ta, the wiring groove pattern and the via pattern are filled with a conductive material such as Cu. Excessive parts of the barrier metal film and the Cu layer are then removed by a CMP method. As a result, a Cu wiring pattern having a desired via contact is formed.

However, in the case of forming the chemically amplified resist film 183 for the formation of a wiring pattern on the silicon nitride film 302 as a reflection preventing film, as shown in FIG. 7, the chemically amplified resist film 231 might not be dissolved by the development and might remain in the via pattern forming hole on the protection film 221.

Also, in the case of performing etching on the SiOC film 163 in contact with or in the vicinity of the remaining chemically amplified resist film 231 so as to form a wiring pattern in the structure shown in FIG. 7, sleeve-like etching residues 241 are formed around the via pattern forming hole in the SiOC film 163, due to the shadowing effect of the non-dissolved part of the chemically amplified resist film 231. This leads to a problem of not being able to form a wiring pattern groove.

Generally, a chemically amplified resist film of a positive type generates acid through exposure, and contains a compound that can change the polarities of a reaction product through a thermal treatment after the exposure. A polarization is caused by the catalytic reaction of the generated acid, and the chemically amplified resist film gains solubility with the developing solution. In this manner, patterning is carried out. On the other hand, a chemically amplified resist film of a negative type contains a compound that cross-links reaction products through a thermal treatment after exposure, and is cross-linked by a catalytic reaction of the generated acid. As a result, the resist film is fixed with the developing solution, and patterning is thus carried out.

In view of the above facts, it can be considered that the dissolution hindering phenomenon observed with the chemically amplified resist film 231 shown in FIGS. 7 and 8 occurs because the acid reaction is hindered. More specifically, in the semiconductor device shown in FIG. 7, it can be considered that a neutralization reaction occurs due to the alkali supplied to the chemically amplified resist film 231.

The growth gases for a SiC film include tetramethylsilane (Si(CH₃)₄) and CO₂. The growth gases for a SiOC film include tetramethylcyclotetrasiloxane (CH₃(H)SiO₄), CO₂, and O₂. The growth gases for a silicon nitride film as a reflection preventing film include SiH₄, NH₃, and N₂.

In view of this, the dissolution hindering phenomenon observed in the chemically amplified resist film 231 in the semiconductor device shown in FIG. 7 using the above growth gases can be considered as follows. The amine group such as NH may be generated in the SiOC film 163, as a NH₃ gas generated during the formation of the silicon nitride film 302 as a reflection preventing film is dissolved, or a N₂ gas is diffused into the SiOC film 163 formed under the silicon nitride film 302 as a reflection preventing film and then reacts with the H group contained in the SiOC film 163. The amine group generated in this manner is supplied to the chemically amplified resist film 231 formed on the protection film 221 in the via hole, and hinders the oxidation reaction of the chemically amplified resist film 231. Thus, the dissolution hindering phenomenon occurs in the chemically amplified resist film 231.

In a case where a SiOC film is employed as an interlayer insulating film and a silicon nitride film is formed as a reflection preventing film on the SiOC film so as to fabricate a semiconductor device having a multilayered interconnection structure using a dual damascene process, the silicon nitride film 302 is formed as the reflection preventing film on the SiOC film 163 in the structure shown in FIG. 7. However, the silicon nitride film 302 contains nitrogen (N), and if the nitrogen reacts with the H group contained in the SiOC film 163, an amine group such as NH is generated in the SiOC film 163. When the amine group reaches the chemically amplified resist film 231 in the via hole, the photooxide is neutralized, resulting in a hindrance to oxidation reaction.

### SUMMARY OF THE INVENTION

A general object of the present invention is to provide semiconductor devices in which the above disadvantages are eliminated.

A more specific object of the present invention is to provide a semiconductor device that has a multilayered interconnection structure using a dual damascene process in which a silicon nitride film is formed as a reflection preventing film on a SiOC film as an interlayer insulating film. This semiconductor device prevents the dissolution hindering effect of the chemically amplified resist film, and has a high precision in patterning.

The above objects of the present invention are achieved by a semiconductor device that includes a substrate and a multilayered interconnection structure formed on the substrate. The multilayered interconnection structure includes: an interlayer insulating film that is made of a silicon oxide film containing carbon; an insulating film that does not contain nitrogen and is formed on the interlayer insulating film; and an insulating film that contains nitrogen and is formed on the insulating film not containing nitrogen.

As the insulating film that does not contain nitrogen is formed between the interlayer insulating film made of a silicon oxide film containing carbon and the insulating film that contains nitrogen, the nitrogen gas generated during the formation of the insulating film containing nitrogen is prevented from diffusing into the interlayer insulating film made of a silicon oxide film containing carbon. Accordingly, the generation of an amine group such as NH due to the reaction of the nitrogen gas with the H group contained in the interlayer insulating film can be prevented. As a result, the dissolution hindering phenomenon in a chemically amplified resist film adjacent to the interlayer insulating film can be prevented, and excellent patterning can be performed for the semiconductor device having a multilayered interconnection structure.

The above objects of the present invention are also achieved by a method of manufacturing a semiconductor device having a multilayered interconnection structure. This method includes the steps of:

forming an interlayer insulating film made of an oxide film containing carbon on a substrate;

forming an insulating film on the interlayer insulating film, using a gas not containing nitrogen;

forming a reflection preventing film on the insulating film;

forming a chemically amplified resist film on the reflection preventing film; and

patterning the chemically amplified resist film.

The above objects of the present invention are also achieved by a method of manufacturing a semiconductor device that includes the steps of:

forming a first interlayer insulating film on a substrate;

forming a second interlayer insulating film made of a silicon oxide film containing carbon on the first interlayer insulating film;

forming an insulating film on the second interlayer insulating film, using a gas not containing nitrogen;

forming a reflection preventing film on the insulating film;

forming a first opening through the first interlayer insulating film and the second interlayer insulating film; and

forming a second opening through the second interlayer insulating film, with a chemically amplified resist film formed on the reflection preventing film being a mask.

The above and other objects and features of the present invention will become more apparent from the following description taken in conjunction with the accompanying drawings.

### BRIEF DESCRIPTION OF THE DRAWINGS

FIGS. 1A and 1B illustrate a conventional process of manufacturing a semiconductor device having a reflection preventing film and a reaction preventing film;

FIG. 2 illustrates the result of an analysis conducted on a USG film and a SiOC film by a FT-IR analysis device;

FIG. 3 illustrates a first step in a conventional process of manufacturing a semiconductor device that employs a SiOC film as an interlayer insulating film;

FIG. 4 illustrates a second step in the conventional process of manufacturing a semiconductor device that employs a SiOC film as an interlayer insulating film;

FIG. 5 illustrates a third step in the conventional process of manufacturing a semiconductor device that employs a SiOC film as an interlayer insulating film;

FIG. 6 illustrates a fourth step in the conventional process of manufacturing a semiconductor device that employs a SiOC film as an interlayer insulating film;

FIG. 7 illustrates a fifth step in the conventional process of manufacturing a semiconductor device that employs a SiOC film as an interlayer insulating film;

FIG. 8 illustrates a sixth step in the conventional process of manufacturing a semiconductor device that employs a SiOC film as an interlayer insulating film;

FIG. 9 illustrates the structure of a semiconductor device in which USG films as interlayer insulating films and SiN films as stoppers and diffusion preventing films are laminated in the dual damascene structure forming area;

FIG. 10 illustrates the structure of a semiconductor device in which FSG films as interlayer insulating films and SiN films as stoppers and diffusion preventing films are laminated in the dual damascene structure forming area;

FIG. 11 illustrates the structure of a semiconductor device in which FSG films as interlayer insulating films and SiC films as stoppers and diffusion preventing films are laminated in the dual damascene structure forming area;

FIG. 12 illustrates the structure of a semiconductor device in which SiOC films as interlayer insulating films and SiC films as stoppers and diffusion preventing films are laminated in the dual damascene structure forming area;

FIG. 13 illustrates the structure of a semiconductor device in which SiOC films as interlayer insulating films and SiC films as stoppers and diffusion preventing films are laminated in the dual damascene structure forming area, and a SiN film is formed as a reflection preventing film on the uppermost SiOC film;

FIG. 14 illustrates the structure of a semiconductor device in which an oxide film is formed between a SiOC film and a SiN film as a reflection preventing film;

FIG. 15 shows the results of experiments that were conducted to determine whether a dissolution hindering phenomenon occurs in a chemically amplified resist film, while varying the type and thickness of an insulating film to be formed between a SiOC film as an interlayer insulating film and a silicon nitride film as a reflection preventing film;

FIG. 16 illustrates a first step in a method of manufacturing a semiconductor device in accordance with a first embodiment of the present invention;

FIG. 17 illustrates a second step in the method of manufacturing a semiconductor device in accordance with the first embodiment of the present invention;

FIG. 18 illustrates a third step in the method of manufacturing a semiconductor device in accordance with the first embodiment of the present invention;

FIG. 19 illustrates a fourth step in the method of manufacturing a semiconductor device in accordance with the first embodiment of the present invention;

FIG. 20 illustrates a fifth step in the method of manufacturing a semiconductor device in accordance with the first embodiment of the present invention;

FIG. 21 illustrates a sixth step in the method of manufacturing a semiconductor device in accordance with the first embodiment of the present invention;

FIG. 22 illustrates a seventh step in the method of manufacturing a semiconductor device in accordance with the first embodiment of the present invention;

FIG. 23 illustrates an eighth step in the method of manufacturing a semiconductor device in accordance with the first embodiment of the present invention;

FIG. 24 illustrates a ninth step in the method of manufacturing a semiconductor device in accordance with the first embodiment of the present invention;

FIG. 25 illustrates a tenth step in the method of manufacturing a semiconductor device in accordance with the first embodiment of the present invention;

FIG. 26 illustrates an eleventh step in the method of manufacturing a semiconductor device in accordance with the first embodiment of the present invention;

FIG. 27 illustrates a twelfth step in the method of manufacturing a semiconductor device in accordance with the first embodiment of the present invention;

FIG. 28 illustrates a thirteenth step in the method of manufacturing a semiconductor device in accordance with the first embodiment of the present invention;

FIG. 29 illustrates a fourteenth step in the method of manufacturing a semiconductor device in accordance with the first embodiment of the present invention;

FIG. 30 illustrates a fifteenth step in the method of manufacturing a semiconductor device in accordance with the first embodiment of the present invention; and

FIG. 31 illustrates a sixteenth step in the method of manufacturing a semiconductor device in accordance with the first embodiment of the present invention.

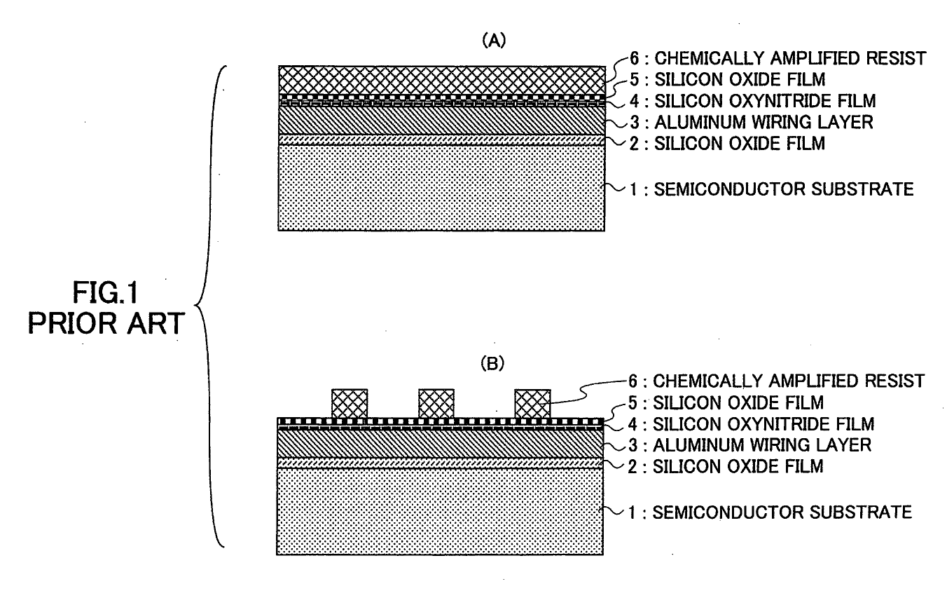

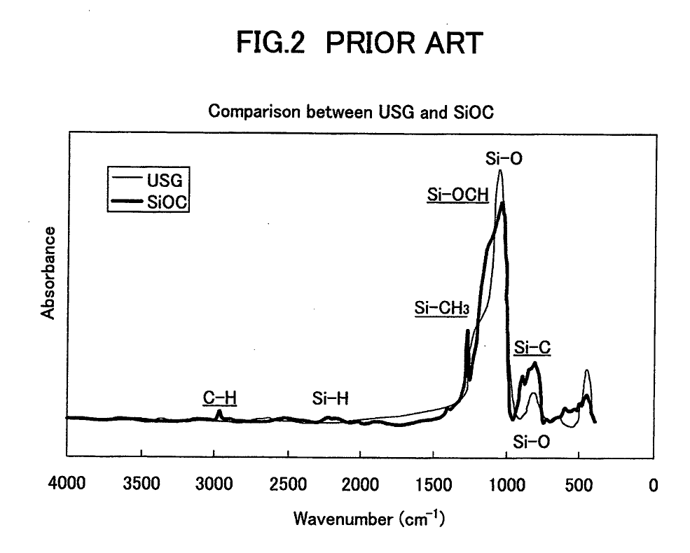

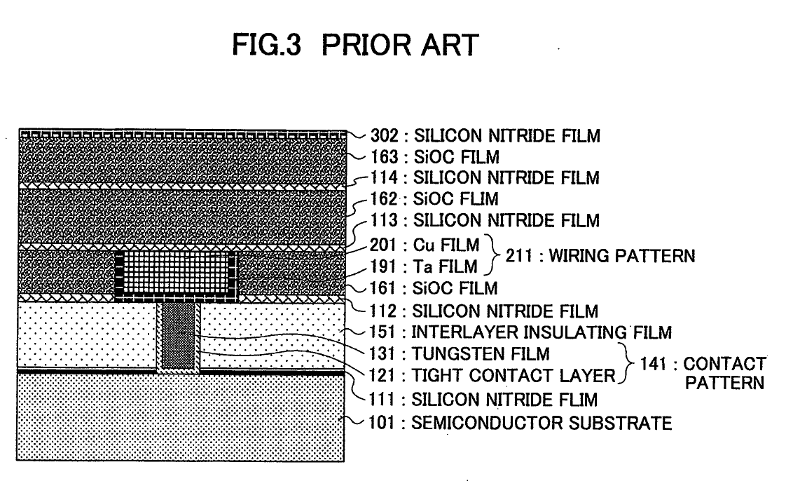

### DESCRIPTION OF THE PREFERRED EMBODIMENTS

The following is a description of embodiments of the present invention, with reference to the accompanying drawings.

The inventors of the present invention made an intensive study on the principles of the present invention. In the course of the study, the inventors conducted experiments in which the combinations of interlayer insulating films and diffusion prevention films as stoppers in a dual damascene structure forming area were changed in various fashions, and a silicon nitride film was formed as a reflection preventing film on the uppermost interlayer insulating film. The inventors observed whether the chemically amplified resist film on the protection film in the via hole would be affected by a dissolution hindering phenomenon. The results of the experiments will be described below.

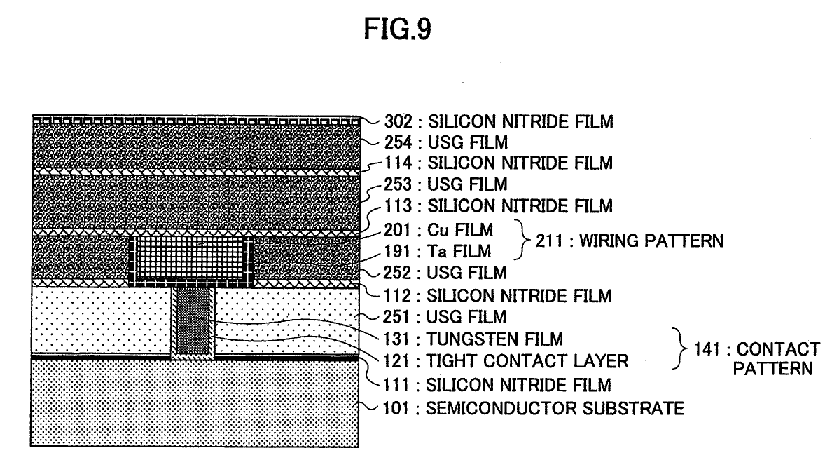

FIG. 9 illustrates the structure of a semiconductor device in which USG films as interlayer insulating films and silicon nitride films as stoppers and diffusion preventing films are laminated in a dual damascene structure forming area.

After the formation of a silicon nitride film 111 and a USG film 251 on a semiconductor substrate 101, a chemically amplified resist film (not shown) for forming a contact hole is pattered on the interlayer insulating film 251 and then subjected to etching, so as to form the contact hole.

A tight contact layer 121 and a tungsten film 131 are then formed in the contact hole. After that, the excessive portions of the tight contact layer 121 and the tungsten film 131 that exist outside the contact hole are removed by a CMP method, and thus a contact pattern 141 is formed.

A silicon nitride film 112, a USG film 252, and a SiN film as a reflection preventing film (not shown) are then formed on the contact pattern 141. A chemically amplified resist film (not shown) for forming a wiring pattern is next patterned on the silicon nitride film as a reflection preventing film (not shown). With the chemically amplified resist film (not shown) for forming a wiring pattern being a mask, etching is performed to form a wiring pattern groove (not shown) through the silicon nitride film as a reflection preventing film (not shown), the silicon nitride film 112, and the USG film 252. A Ta film 191 and a Cu film 201 are then formed inside the wiring pattern groove (not shown), and the excessive portions of the Ta film 191 and the Cu film 201 that exist outside the wiring pattern groove are removed by a CMP method. In this manner, a wiring pattern 211 is formed.

A silicon nitride film 113, a USG film 253, a silicon nitride film 114, a USG film 254, and a silicon nitride film 302 as a reflection preventing film, are then formed on the wiring pattern 211.

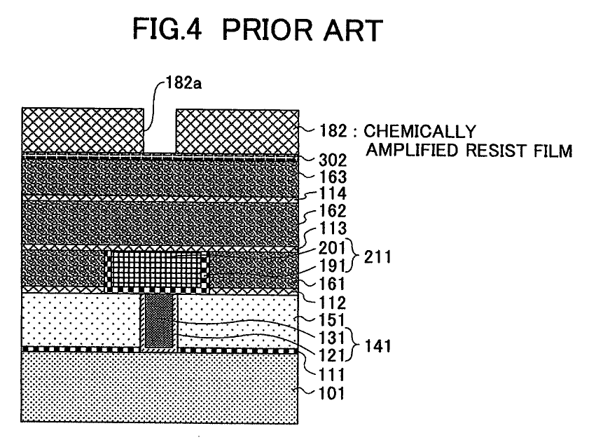

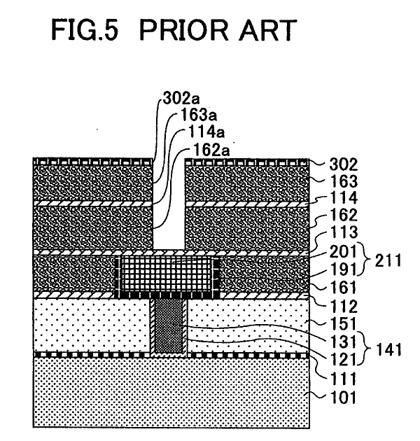

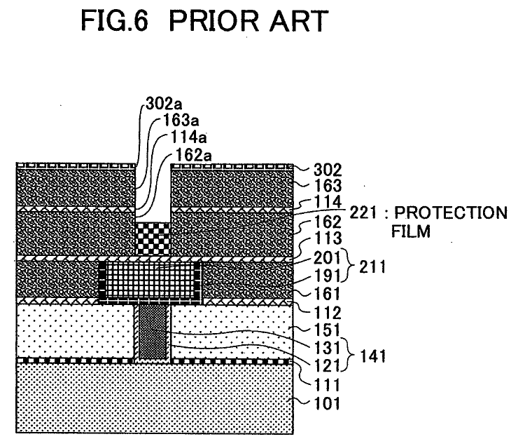

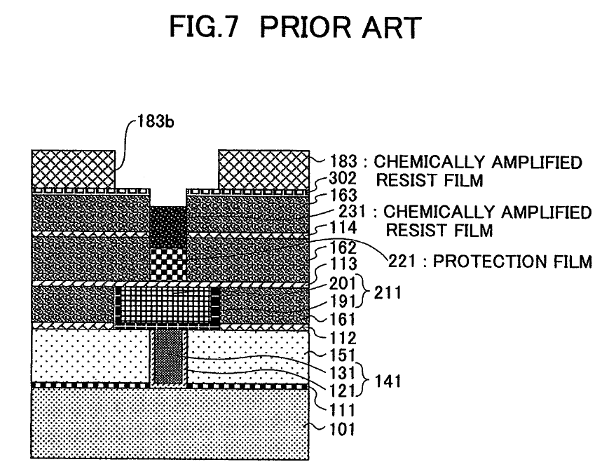

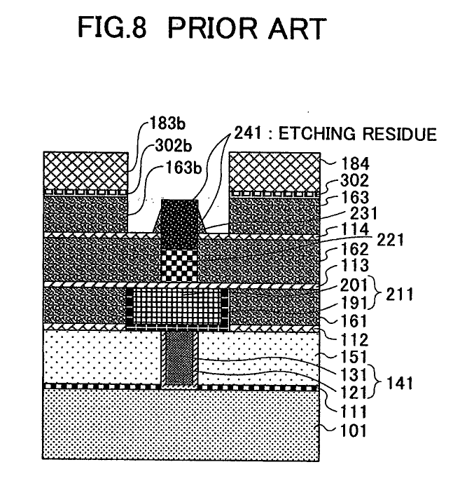

In a semiconductor device of this structure shown in FIG. 9, the inventors formed a dual damascene structure in the same manner as in the procedures of manufacturing the conventional semiconductor device shown in FIGS. 4 through 8. As a result, the dissolution hindering phenomenon described above was not observed with the chemically amplified resist film.

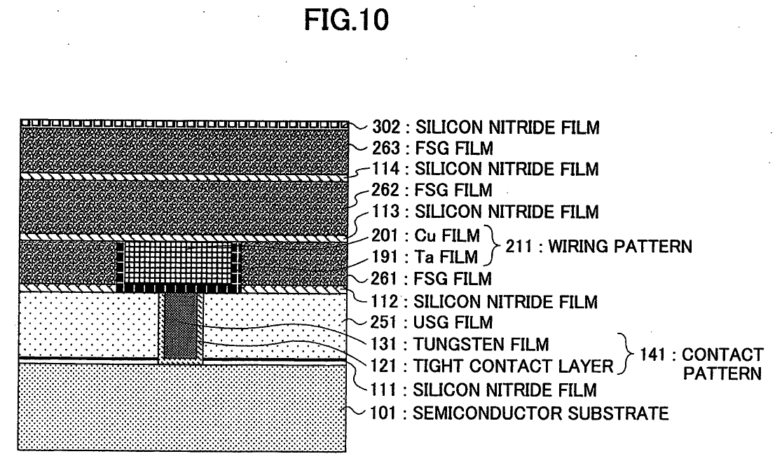

FIG. 10 illustrates the structure of a semiconductor device in which FSG films as interlayer insulating films and silicon nitride films as stoppers and diffusion preventing films are laminated in the dual damascene structure forming area.

In this structure, the procedures up to the formation of a contact pattern are the same as the procedures of manufacturing the semiconductor device shown in FIG. 9. Accordingly, like reference numerals are given to like components, and explanation of them will be omitted in the following description.

After the formation of a contact pattern 141, a silicon nitride film 112, a FSG film 261, and a silicon nitride film as a reflection preventing film (not shown), are formed on the contact pattern 141. A chemically amplified resist film (not shown) for forming a wiring pattern is then patterned on the silicon nitride film as a reflection preventing film (not shown). With the chemically amplified resist film (not shown) for forming a wiring pattern being a mask, etching is performed to form a wiring pattern groove (not shown) through the SiN film as a reflection preventing film (not shown), the silicon nitride film 112, and the FSG film 261. A Ta film 191 and a Cu film 201 are then formed inside the wiring pattern groove (not shown). The excessive portions of the Ta film 191 and the Cu film 201 that exist outside the wiring pattern groove (not shown) are removed by a CMP method. Thus, a wiring pattern 211 is formed.

A silicon nitride film 113, a FSG film 262, a silicon nitride film 114, a FSG film 263, and a silicon nitride film 302 as a reflection preventing film, are then formed on the wiring pattern 211.

In a semiconductor device having this structure shown in FIG. 10, the inventors formed a dual damascene structure in the same manner as in the procedures of manufacturing the conventional semiconductor device shown in FIGS. 4 through 8. As a result, the dissolution hindering phenomenon was not observed with the chemically amplified resist film.

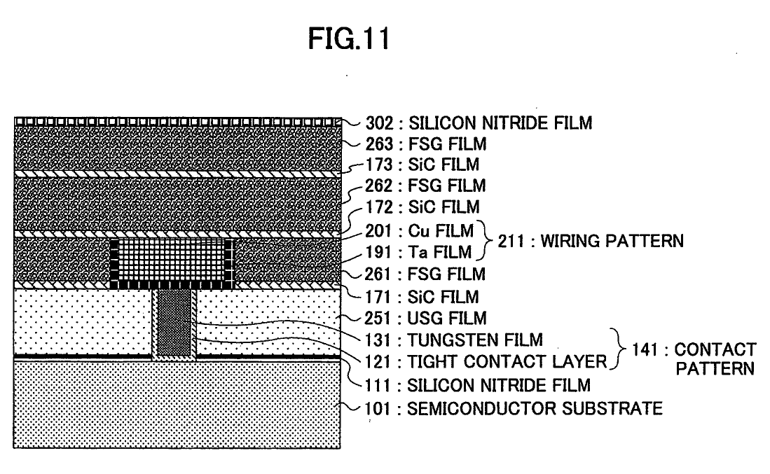

FIG. 11 illustrates the structure of a semiconductor device in which FSG films as interlayer insulating films and SiC films as stoppers and diffusion preventing films are formed in the dual damascene forming area.

In this structure, the procedures up to the formation of a contact pattern are the same as the procedures of manufacturing the semiconductor device shown in FIG. 9. Accordingly, like reference numerals are given to like components, and explanation of them will be omitted in the following description.

After the formation of a contact pattern 141, a SiC film 171, a FSG film 261, and a silicon nitride film as a reflection preventing film (not shown), are formed on the contact pattern 141. A chemically amplified resist film (not shown) for forming a wiring pattern is then patterned on the silicon nitride film as a reflection preventing film (not shown). With the chemically amplified resist film (not shown) for forming a wiring pattern being a mask, etching is performed to form a wiring pattern groove (not shown) through the silicon nitride film as a reflection preventing film (not shown), the SiC film 171, and the FSG film 261. A Ta film 191 and a Cu film 201 are then formed inside the wiring pattern groove (not shown). The excessive portions of the Ta film 191 and the Cu film 201 that exist outside the wiring pattern groove are removed by a CMP method. Thus, a wiring pattern 211 is formed.

A SiC film 172, a FSG film 262, a SiC film 173, a FSG film 263, and a silicon nitride film 302 as a reflection preventing film, are then formed on the wiring pattern 211.

In a semiconductor device having this structure shown in FIG. 11, the inventors formed a dual damascene structure in the same manner as in the procedures of manufacturing the conventional semiconductor device shown in FIGS. 4 through 8. As a result, the dissolution hindering phenomenon described above was not observed with the chemically amplified resist film.

In the above manner, it was confirmed that the dissolution hindering phenomenon was not observed in any of the combinations of interlayer insulating films, silicon nitride films as stoppers and diffusion preventing films, and a silicon nitride film as a reflection preventing film, as shown in FIGS. 9 through 11.

The inventors next conducted an experiment of forming a dual damascene structure in each of the following two semiconductor devices: one was a semiconductor device in which a silicon nitride film as a reflection preventing film was formed on a SiOC film as an interlayer insulating film; and the other was a semiconductor device in which a silicon nitride film as a reflection preventing film was not formed on a SiOC film as an interlayer insulating film.

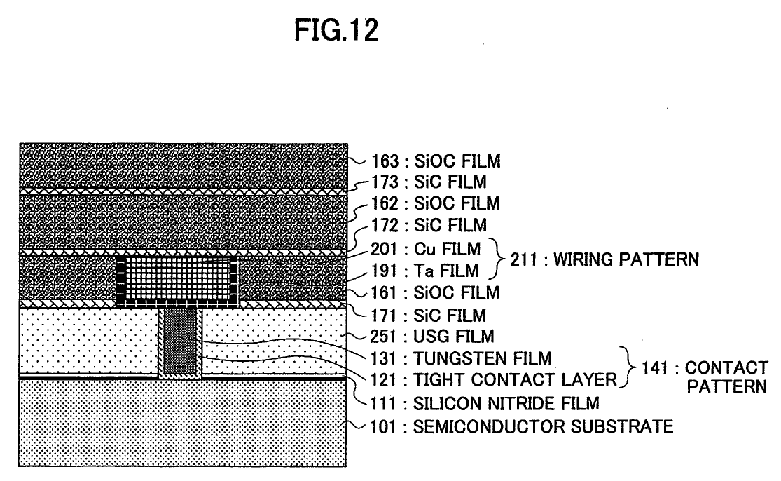

FIG. 12 illustrates the structure of a semiconductor device in which SiOC films as interlayer insulating films and SiC films as stoppers and diffusion preventing films are laminated in the dual damascene structure forming area.

In this structure, the procedures up to the formation of a contact pattern are the same as the procedures of manufacturing the semiconductor device shown in FIG. 9. Accordingly, like reference numerals are given to like components, and explanation of them will be omitted in the following description.

After the formation of a contact pattern 141, a SiC film 171, a SiOC film 161, and a silicon nitride film as a reflection preventing film (not shown), are formed on the contact pattern 141. A chemically amplified resist film (not shown) for forming a wiring pattern is then patterned on the silicon nitride film as a reflection preventing film (not shown). With the chemically amplified resist film (not shown) for forming a wiring pattern being a mask, etching is performed to form a wiring pattern groove (not shown) through the silicon nitride film as a reflection preventing film (not shown), the SiC film 171, and the SiOC film 161. A Ta film 191 and a Cu film 201 are then formed inside the wiring pattern groove (not shown). The excessive portions of the Ta film 191 and the Cu film 201 that exist outside the wiring pattern groove are removed by a CMP method. Thus, a wiring pattern 211 is formed.

A SiC film 172, a SiOC film 162, a SiC film 173, and a SiOC film 163, are then formed on the wiring pattern 211.

In a semiconductor device having this structure shown in FIG. 12, the inventors formed a dual damascene structure in the same manner as in the procedures of manufacturing the conventional semiconductor device shown in FIGS. 4 through 8. As a result, the dissolution hindering phenomenon described above was not observed with the chemically amplified resist film.

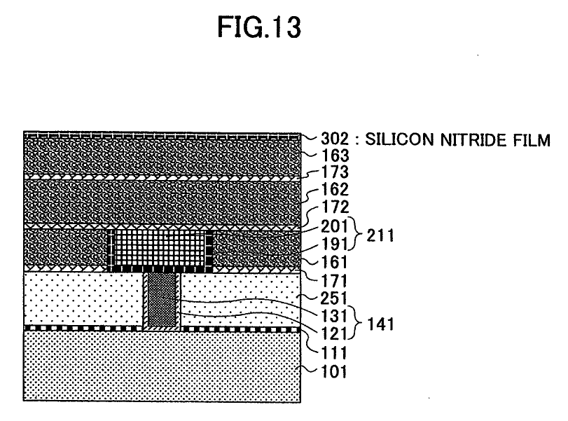

FIG. 13 illustrates the structure of a semiconductor device in which SiOC films as interlayer insulating films and SiC films as stoppers and diffusion preventing films are laminated in the dual damascene structure forming area, and a silicon nitride film is formed as a reflection preventing film on the uppermost SiOC film.

The semiconductor device shown in FIG. 13 is achieved by forming a silicon nitride film 302 as a reflection preventing film on the SiOC film 163 of the same structure as the semiconductor device shown in FIG. 12.

In FIG. 13, the same components as in the foregoing drawings are denoted by the same reference numerals as well, and explanation of them is omitted herein.

In the semiconductor device having the structure shown in FIG. 13, the inventors formed a dual damascene structure in the same manner as in the procedures of manufacturing the conventional semiconductor device shown in FIGS. 4 through 8. As a result, the dissolution hindering phenomenon described above was observed with the chemically amplified resist film.

Judging from the results of the experiments conducted on the semiconductor devices shown in FIGS. 9 through 13, the inventors came to a conclusion that the dissolution hindering phenomenon occurred in the chemically amplified film in each case where a dual damascene structure is formed after the formation of a silicon nitride film as a reflection preventing film on a SiOC film as an interlayer insulating film. As described earlier, the reason of the dissolution hindering phenomenon is that the oxidation reaction of the chemically amplified resist film 231 is hindered to a great degree. This is because the N₂ gas generated during the formation of the silicon nitride film 302 as a reflection preventing film is diffused into the SiOC film 163 formed under the silicon nitride film 302 as a reflection preventing film, and reacts with the H group contained in the SiOC film 163 to generate an amine group such as NH in the SiOC film 163. The amine group is supplied to the chemically amplified resist film 231 formed on the protection film 221 within the via hole, thereby causing the dissolution hindering phenomenon in the chemically amplified resist film 231.

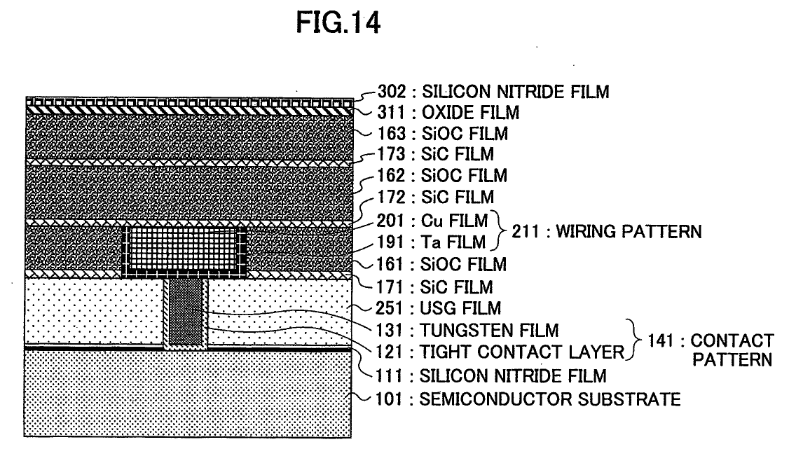

FIG. 14 illustrates the structure of a semiconductor device in which an oxide film 311 is formed between the SiOC film 163 and the SiN film 302 as a reflection preventing film of the semiconductor device shown in FIG. 13.

The oxide film 311 shown in FIG. 14 is a diffusion preventing film that prevents the diffusion of the N₂ gas, which is generated during the formation of the silicon nitride film 302, into the SiOC film 163. By doing so, the oxide film 311 prevents the generation of an amine group in the SiOC film 163.

FIG. 15 shows the results of an experiment conducted to determine whether the dissolution hindering phenomenon in the chemically amplified resist film can be observed. In this experiment, a SiH₄-type USG film (the refraction index: 1.47) having a film thickness of 50 nm, a SiH₄-type USG film (the refraction index: 1.47) having a film thickness of 100 nm, a SiH₄-type USG film (the refraction index: 1.51) having a film thickness of 100 nm, a TEOS-type USG film (the refraction index: 1.46) having a film thickness of 30 nm, and a TEOS-type USG film (the refraction index: 1.46) having a film thickness of 30 nm, were each formed as the oxide film 311. A dual damascene structure was then formed in the same manner as in the conventional procedures shown in FIGS. 4 through 8.

As the growth gases for the SiH₄-type USG films (the refraction index: 1.47) and the SiH₄-type USG film (the refraction index: 1.51), SiH₄, N₂O, and N₂, were used. As the growth gases for the TEOS-type USG films (the refraction index: 1.46), TEOS (tetraethoxysilane, Si(OC₂H₅)₄) and O₂ were used.

In view of this, FIG. 15 shows the results of an experiment conducted to determine whether the dissolution hindering phenomenon occurs in a chemically amplified resist film with insulating films of various types and film thicknesses formed between a SiOC film as an interlayer insulating film and a silicon nitride film as a reflection preventing film.

As can be seen from FIG. 15, the dissolution hindering phenomenon in the chemically amplified resist film (not shown) was observed with the SiH₄-type USG films (the refraction index: 1.47) and the SiH₄-type USG film (the refraction index: 1.51).

This is because the N₂O or N₂ contained in the growth gases for the SiH₄-type USG film diffused into the SiOC film 163 and generated an amine group in the SiOC film 163. The amine group was supplied to the chemically amplified resist film (not shown), and hindered the oxidation reaction of the chemically amplified resist film. On the other hand, the growth gases for the TEOS-type USG films (the refraction index: 1.46) did not include N₂O or N₂, and each functioned as a diffusion preventing film accordingly. As a result, the dissolution hindering phenomenon did not occur in the chemically amplified resist film (not shown).

In view of this, it is preferable to form a dual damascene structure after forming a film not containing N as a growth gas, such as a TEOS-type USG film, between a SiOC film and a SiN film as a reflection preventing film in a semiconductor device. The film not containing N as a growth gas should have a film thickness of approximately 30 nm.

### First Embodiment

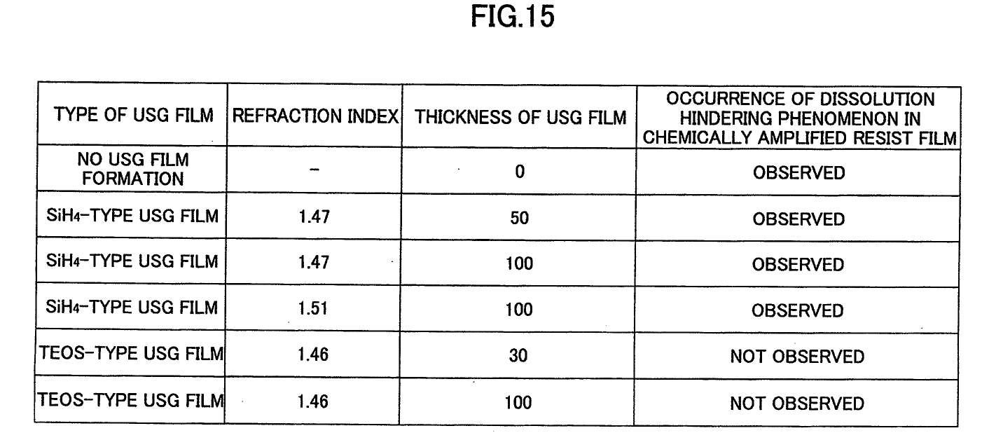

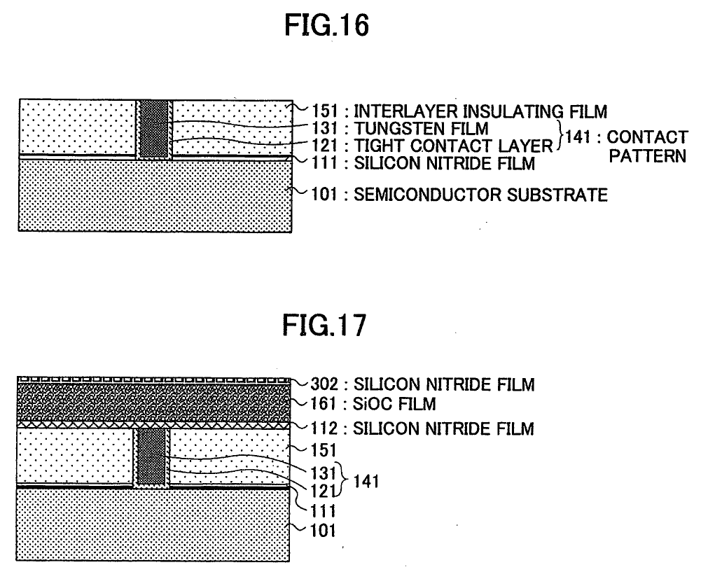

FIGS. 16 through 31 illustrate a process of manufacturing a semiconductor device in accordance with a first embodiment of the present invention. In this manufacturing process, a SiOC film that is an interlayer insulating film is patterned using a dual damascene process and a reflection preventing film.

### Step of Forming a Contact Pattern

Referring to FIG. 16, after the formation of a circuit device (not shown) on a semiconductor substrate 101, a silicon nitride film 111 and a silicon oxide film 151 are formed on the semiconductor substrate 101. To flatten the area of the circuit device (not shown), the silicon oxide film 151 is polished by a CMP method. After that, a chemically amplifier resist film for forming a contact pattern (not shown) is patterned on the silicon oxide film 151. With the chemically amplified resist film being the mask, etching is performed to form a contact hole (not shown). A tight contact layer 121 and a tungsten film 131 are then formed in the contact hole. A contact pattern 141 is formed, with the tight contact layer 121 and the tungsten film 131 being left only within the contact hole, by a CMP method.

### Step of Forming an Interlayer Insulating Film

Referring next to FIG. 17, a silicon nitride film 112, a SiOC film 161, and a silicon nitride film 301 as a reflection preventing film, are formed on the contact pattern 141.

As the source gas for the SiOC film, a gas such as Si(CH₃)₄ or Si(CH₃)₃ is employed in accordance with a plasma CVD method. Examples of actual processes includes the Concept Two Sequel (developed by Novellus), and gases used in these examples include CH₃(H)SiO₄, CO₂, and O₂— Unlike a USG film, a SiOC film contains a C—H group, a Si—CH₃ group, a Si—C group, and a Si—OCH group.

### Step of Patterning a Chemically Amplified Resist Film for Forming a Wiring Pattern

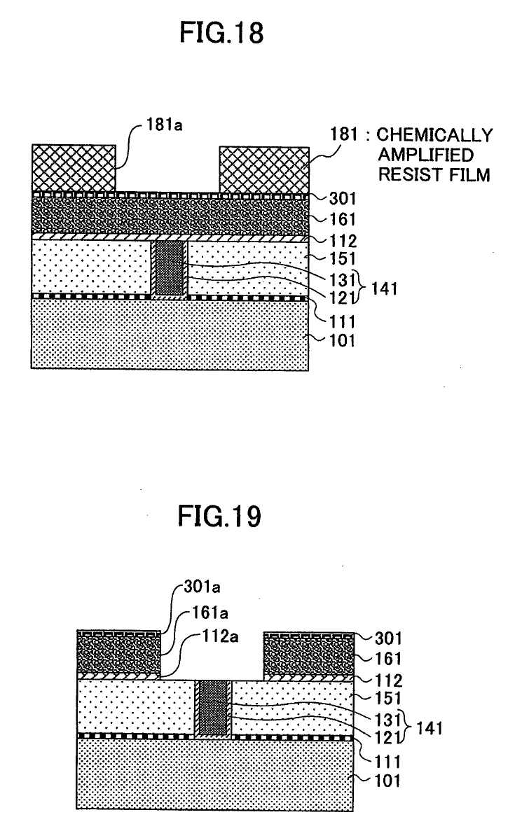

Referring next to FIG. 18, a chemically amplified resist film 181 for forming a wiring pattern is patterned on the silicon nitride film 301 as a reflection preventing film, so as to form an opening 181a.

### Step of Forming a Wiring Pattern Groove

Referring next to FIG. 19, etching is performed on the silicon nitride film 112, the SiOC film 161, the silicon nitride film 301 as a reflection preventing film, with the chemically amplified resist film 181 being a mask. The opening 181a is thus transferred to form an opening 112a in the silicon nitride film 112, an opening 161a in the SiOC film 161, and an opening 301a in the silicon nitride film 301 as a reflection preventing film.

### Step of Forming Films for a Wiring Pattern

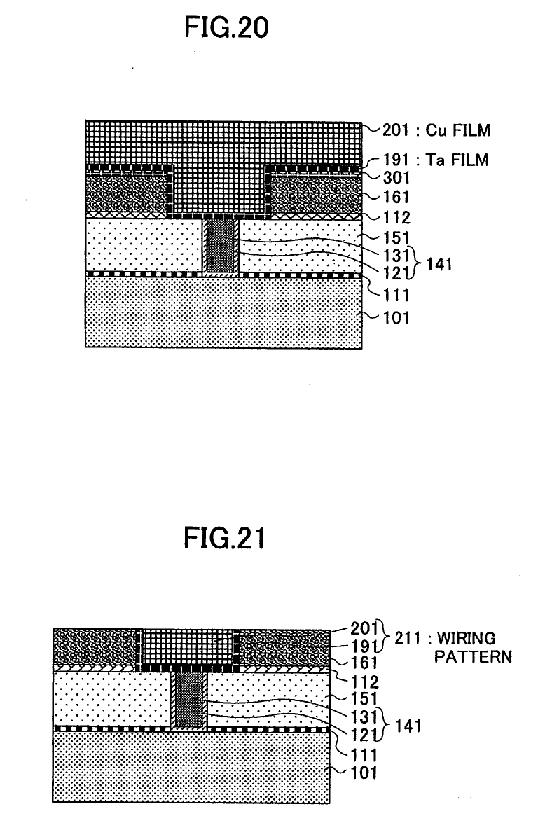

Referring next to FIG. 20, a Ta film and a Cu film are formed in the opening 112a in the silicon nitride film 112, the opening 161a in the SiOC film 161, and the opening 301a in the silicon nitride film 301 as a reflection preventing film.

### Step of Forming a Wiring Pattern by a CMP Method

Referring next to FIG. 21, polishing is performed on the semiconductor device having the structure shown in FIG. 20, so as to form a wiring pattern 211.

### Step of Forming an Interlayer Insulating Film for Forming a Dual Damascene Structure

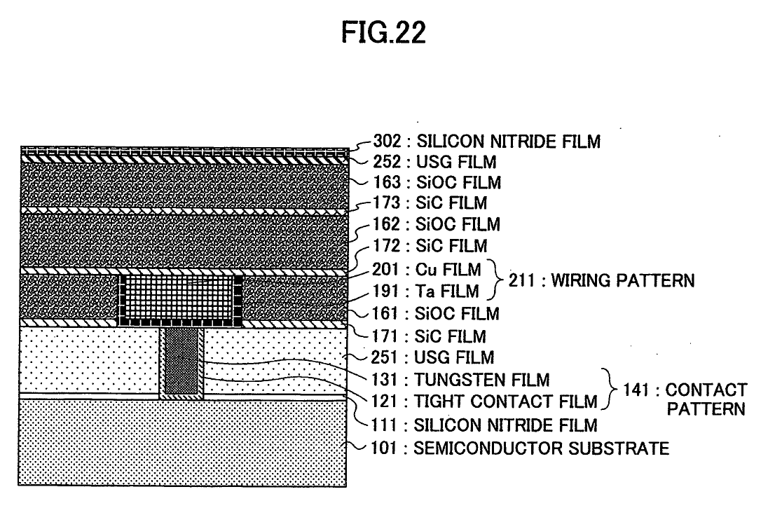

Referring next to FIG. 22, a SiC film 172, a SiOC film 162, a SiC film 173, a SiOC film 163, a USG film 252 as a diffusion preventing film, and a silicon nitride film 302 as a reflection preventing film, are formed on the wiring pattern 211.

The USG film 252 may be a TEOS-type USG film that does not contain N₂O or N₂ as a growth gas and has a thickness of 30 nm. As long as N₂O or N₂ are not contained as a growth gas, any film other than a USG film can function as a diffusion preventing film to prevent the N₂ gas contained in the silicon nitride film 301 as a reflection preventing film from diffusing into the SiOC film 163, and also to prevent generation of an amine group in the SiOC film 163.

### Step of Forming a Chemically Amplified Resist Film For Forming a Via Pattern

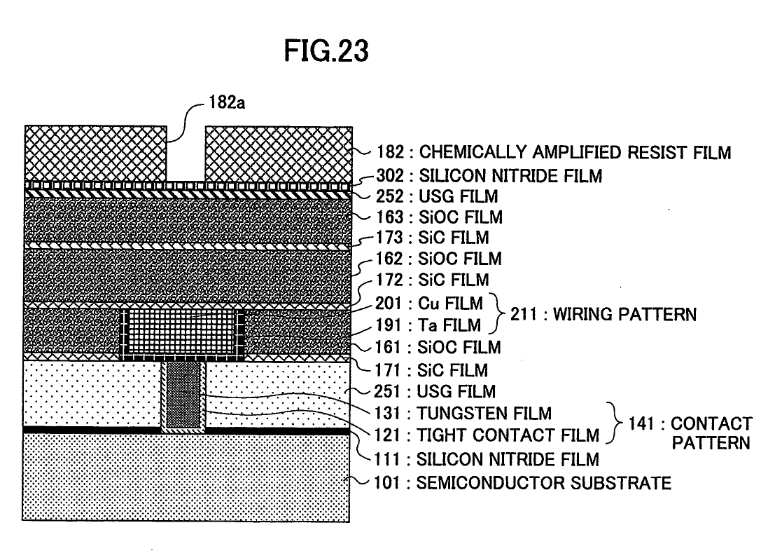

Referring next to FIG. 23, a chemically amplified resist film 182 for forming a via pattern to have conduction with the wiring pattern 211 is patterned on the SiN film 302 as a reflection preventing pattern. An opening 182a is thus formed.

### Step of Performing Etching to Form a Via Pattern

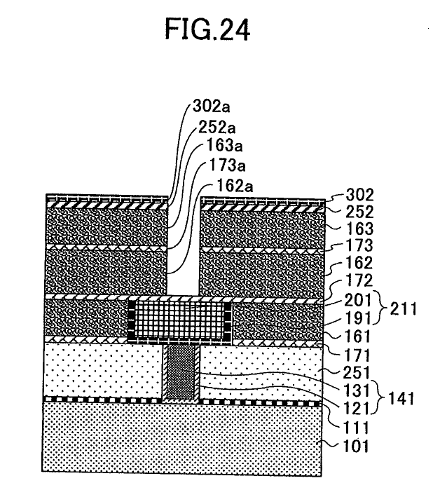

Referring next to FIG. 24, etching is performed, with the chemically amplified resist film 182 being a mask. As a result, the opening 182a is transferred to form an opening 162a in the SiOC film 162, an opening 173a in the SiC film 173, an opening 163a in the SiOC film 163, an opening 252a in the USG film 252, and an opening 302a in the silicon nitride film 302 as a reflection preventing film.

### Step of Forming a Protection Film

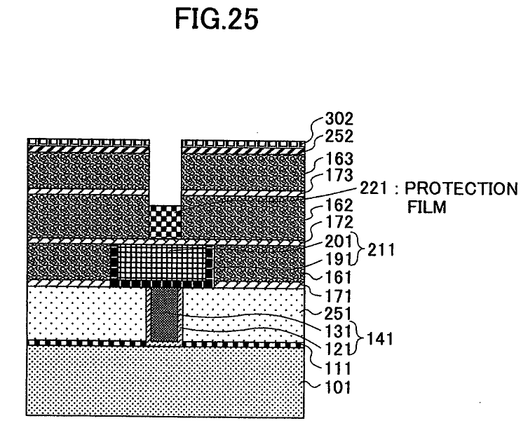

Referring next to FIG. 25, a protection film 221 made of a resin material is formed on the SiC film 172, so as to protect the SiC film 172 at the time of etching.

### Step of Patterning a Chemically Amplified Resist Film for Forming a Wiring Pattern

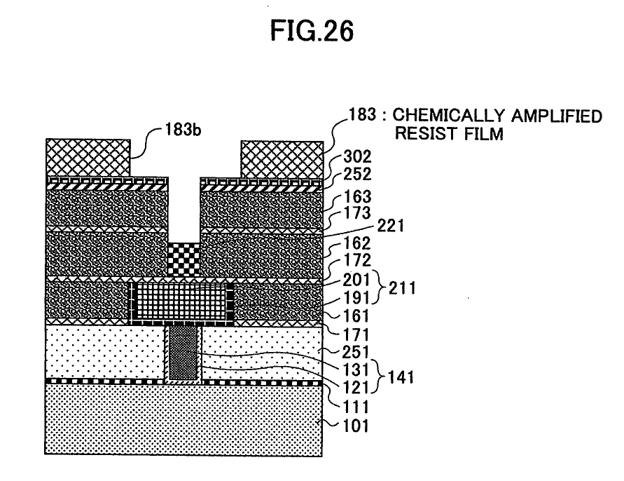

Referring next to FIG. 26, a chemically amplified resist film 183 for forming a wiring pattern is patterned on the silicon nitride film 302 as a reflection preventing film. An opening 183b is thus formed.

### Step of Forming a Wiring Pattern Groove

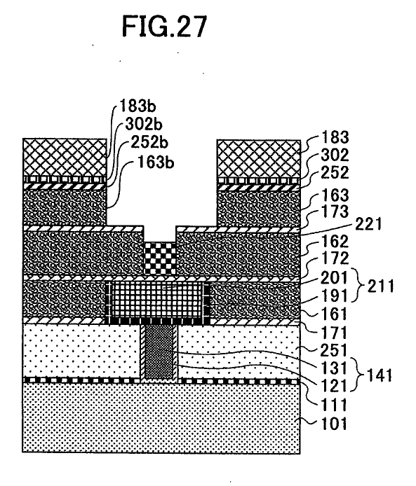

Referring next to FIG. 27, etching is performed on the SiOC film 163, the USG film 252 as a diffusion preventing film, and the silicon nitride film 302 as a reflection preventing film, with the chemically amplified resist film 183 being a mask. As a result, the opening 183b is transferred to form an opening 163b in the SiOC film 163, an opening 252b in the USG film 252 as a diffusion preventing film, and an opening 302b in the silicon nitride film 302 as a reflection preventing film.

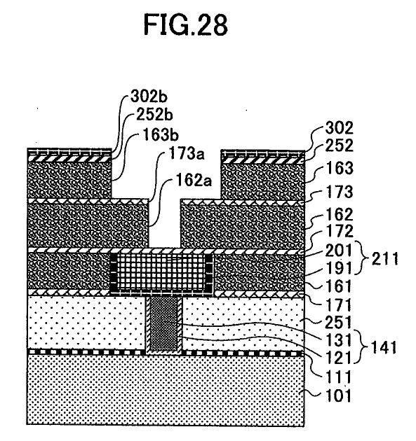

In the step shown in FIG. 28, the remaining chemically amplified resist film 183 and the remaining protection film 221 are removed by ashing.

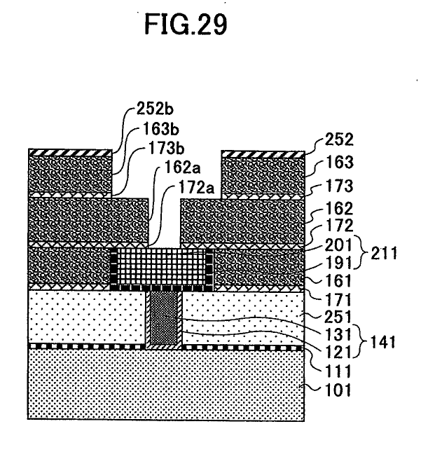

In the step shown in FIG. 29, etching is performed on the SiN film 302 as a reflection preventing film on the USG film 252, the SiC film 173, and the SiC film 172, so as to form an opening 173b in the SiC film 173 and an opening 172a in the SiC film 172. The SiC film 173 is subjected to the etching, with the opening 252b in the USG film 252 being a mask. The SiC film 172 is subjected to the etching, with the opening 162a in the SiOC film 162 being a mask.

### Step of Forming a Film for Forming a Wiring Pattern

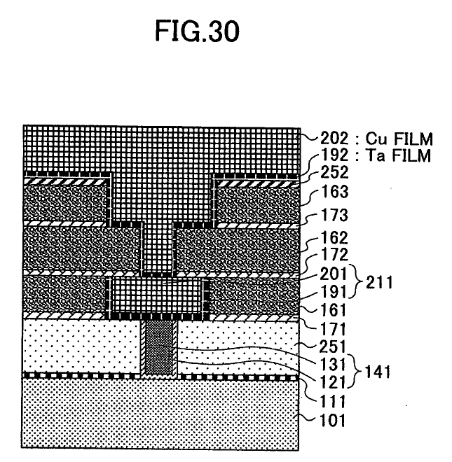

Referring next to FIG. 30, a Ta film 192 and a Cu film 202 are formed inside the opening 252b, the opening 163b, the opening 173b, the opening 162a, and the opening 172a shown in FIG. 29.

### Step of Forming a Wiring Pattern and a Via Pattern by a CMP Method

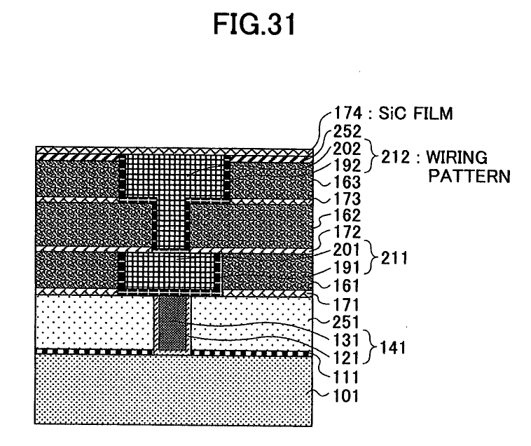

Referring next to FIG. 31, polishing is performed by a CMP method, and a SiC film as a diffusion preventing film is formed on the USG film 252 and a wiring pattern 212.

In the case where a SiOC film is patterned using a reflection preventing film in a semiconductor device having a dual damascene structure with SiOC films in the above described manner, the dual damascene structure should be formed after the formation of a film not containing N as a growth gas, such as a TEOS-type USG film, between the SiOC film and a silicon nitride film as a reflection preventing film, so as to effectively prevent the dissolution hindering phenomenon in the chemically amplified resist film. The film thickness of such a TEOS-type USG film should be approximately 30 nm.

### Second Embodiment

Although the USG film 252 as a diffusion preventing film is formed between the SiOC film 163 and the silicon nitride film 302 as a reflection preventing film in the first embodiment of the method of manufacturing a semiconductor device, a SiC film not containing N as a growth gas may be employed instead of the USG film 252.

The growth gases for a SiC film include tetramethylsilane (Si(CH₃)₄) and CO₂, as described earlier.

A SiC film as a diffusion preventing film is formed on the SiOC film 163, and the silicon nitride film 302 as a reflection preventing film is then formed on the SiC film. With this structure, the N₂ gas generated during the formation of the silicon nitride film 302 as a reflection preventing film can be prevented from diffusing into the SiOC film 163 formed under the silicon nitride film 302 as a reflection preventing film. Also, the N₂ gas can be prevented from reacting with the H group contained in the SiOC film 163, and generation of an amine group such as NH in the SiOC film 163 can be prevented. Thus, the dissolution hindering phenomenon in the chemically amplified resist film can be effectively avoided.

### Third Embodiment

Although the USG film 252 as a diffusion preventing film is formed between the SiOC film 163 and the silicon nitride film 302 as a reflection preventing film in the first embodiment of the method of manufacturing a semiconductor device, a PSG film not containing N as a growth gas may be employed instead of the USG film 252.

The growth gases for a PSG film include PH₃, O₂, and He.

More specifically, a PSG film as a diffusion preventing film is formed on the SiOC film 163, and the silicon nitride film 302 as a reflection preventing film is then formed on the PSG film. With this structure, the N₂ gas generated during the formation of the silicon nitride film 302 as a reflection preventing film can be prevented from diffusing into the SiOC film 163 formed under the SiN film 302. Also, the N₂ gas can be prevented from reacting with the H group in the SiOC film 163, and generation of an amine group such as NH in the SiOC film 163 can be prevented. Thus, the dissolution hindering phenomenon in the chemically amplified resist film can be effectively avoided.

### Fourth Embodiment

Although the USG film 252 as a diffusion preventing film is formed between the SiOC film 163 and the silicon nitride film 302 as a reflection preventing film in the first embodiment of the method of manufacturing a semiconductor device, a SiOC film that does not contain N as a growth gas and has a higher film density than the SiOC film 163 may be employed instead of the USG film 252.

The growth gases for such a SiOC film include tetramethylcyclotetrasiloxane (CH₃(H) SiO₄), CO₂, and O₂.

More specifically, a SiOC film having a high film density is formed as a diffusion preventing film on the SiOC film 163, and the silicon nitride film 302 as a reflection preventing film is then formed on the SiOC film having a high film density. With this structure, the N₂ gas generated during the formation of the silicon nitride film 302 as a reflection preventing film can be prevented from diffusing into the SiOC film 163 formed under the silicon nitride film 302. Also, the N₂ gas can be prevented from reacting with the H group contained in the SiOC film 163, and generation of an amine group such as NH in the SiOC film 163 can be prevented. Thus, the dissolution hindering phenomenon in the chemically amplified resist film can be effectively avoided.

It should be noted that the present invention is not limited to the embodiments specifically disclosed above, but other variations and modifications may be made without departing from the scope of the present invention.

What is claimed is:

1. A method of manufacturing a semiconductor device having a multilayered interconnection structure,
the method comprising the steps of:
forming an interlayer insulating film made of an oxide film containing carbon on a substrate;
forming an insulating film on the interlayer insulating film, using a gas not containing nitrogen;
forming a reflection preventing film on the insulating film;
forming a chemically amplified resist film on the reflection preventing film; and
patterning the chemically amplified resist film.

2. A method of manufacturing a semiconductor device, comprising the steps of:
forming a first interlayer insulating film on a substrate;
forming a second interlayer insulating film made of a silicon oxide film containing carbon on the first interlayer insulating film;
forming an insulating film on the second interlayer insulating film, using a gas not containing nitrogen;
forming a reflection preventing film on the insulating film;
forming a first opening through the first interlayer insulating film and the second interlayer insulating film; and
forming a second opening through the second interlayer insulating film, with a chemically amplified resist film formed on the reflection preventing film being a mask.

3. The method as claimed in claim 2, wherein the first interlayer insulating film and the second interlayer insulating film are made of silicon oxide films containing carbon.

4. The method as claimed in claim 2, wherein the silicon oxide film containing carbon is a porous film.

5. The method as claimed in claim 2, wherein the insulating film is formed by a CVD method using a TEOS gas.

6. The method as claimed in claim 2, wherein the insulating film is formed with a SiC film using tetramethylsilane (Si(CH₃)₄) and CO₂ as growth gases.

7. The method as claimed in claim 2, wherein the insulating film is formed with a PSG film.

8. The method as claimed in claim 2, wherein the insulating film is formed with a SiOC film having a higher density than the first and second interlayer insulating films, using tetramethylcyclotetrasiloxane (CH₃(H)SiO₄), CO₂, and O₂, as growth gases.

9. The method as claimed in claim 2, wherein the reflection preventing film is formed with a SiN film using SiH₄, NH₃, and N₂ as growth gases.

10. The method as claimed in claim 2, wherein the insulating film has a film thickness of 100 nm or smaller.

11. The method as claimed in claim 2, wherein the insulating film has a film thickness of 30 nm or smaller.
